(19) United States
(12) Patent Application Publication
(10) Pub. No.: US 2024/0222484 A1
(43) Pub. Date: Jul. 4, 2024

(54) TRANSISTOR WITH CHANNEL MATERIAL IN A STACK WITH INSULATOR MATERIAL SUPPORTS

(71) Applicant: Intel Corporation, Santa Clara, CA (US)

(72) Inventors: Chia-Ching Lin, Portland, OR (US); Kevin P. O'Brien, Portland, OR (US); Ashish Verma Penumatcha, Beaverton, OR (US); Chelsey Dorow, Portland, OR (US); Kirby Maxey, Hillsboro, OR (US); Carl H. Naylor, Portland, OR (US); Tao Chu, Portland, OR (US); Guowei Xu, Portland, OR (US); Uygar Avci, Portland, OR (US); Feng Zhang, Hillsboro, OR (US); Ting-Hsiang Hung, Beaverton, OR (US); Ande Kitamura, Portland, OR (US); Mahmut Sami Kavrik, Eugene, OR (US)

(73) Assignee: Intel Corporation, Santa Clara, CA (US)

(21) Appl. No.: 18/092,152

(22) Filed: Dec. 30, 2022

(51) Int. Cl. H01L 29/76; H01L 21/02; H01L 29/06; H01L 29/24; H01L 29/423; H01L 29/66; H01L 29/775

(52) U.S. Cl. CPC H01L 29/7606; H01L 21/02568; H01L 21/02603; H01L 29/0673; H01L 29/24; H01L 29/42392; H01L 29/66969; H01L 29/775

(57) ABSTRACT

Transistors and integrated circuitry including a 2D channel material layer within a stack of material layers further including one or more insulator (e.g., dielectric) materials above and/or below the 2D channel material layer. These supporting insulator layers may be non-sacrificial while other material layers within a starting material stack may be sacrificial, replaced, for example, with gate insulator and/or gate material. In some exemplary embodiments, the 2D channel material is a metal chalcogenide and the supporting insulator layer is advantageously a dielectric material composition having a low dielectric constant.

### BACKGROUND

For integrated circuits, the performance of silicon-based transistors drops significantly at reduced gate lengths, particularly in the context of gate-all-around (GAA) or nanoribbon or wire (RoW) transistors. In such devices, the reduced thickness of the silicon semiconductor material has a detrimental impact on the charge carrier mobility. This issue has motivated development of non-silicon materials.

One class of non-silicon materials is a compound of one or more metals and one or more chalcogens. Transition metal dichalcogenides (TMD or TMDC) are one exemplary species of the metal chalcogen class of materials. TMDCs display semiconductor properties as a unit cell of MX₂, where M is a transition metal atom (e.g., Mo, W) and X is a chalcogen atom other than oxygen (S, Se, or Te). Metal chalcogenide materials have been of significant interest in highly-scaled integrated circuitry. One advantage is the thin active layers possible. A metal chalcogenide-channeled transistor may therefore have excellent short channel properties. It has also been shown that many metal chalcogen materials have good electron and hole mobility, making them interesting for complementary short channel devices (e.g., L_{g}<20 nm).

TMD channel materials offer high mobility even when very thin (e.g., about 1 nm) and so are often referred to as a 2D material. Other 2D materials suitable for transistor structures are also known, with graphene being one example. However, implementing such 2D channel materials in transistor structures faces many practical challenges. For example, the mechanical strength of such thin layers may be insufficient to survive transistor fabrication.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods for forming a transistor structure having insulator material layers above and/or below a channel material layer, in accordance with some embodiments;

FIGS. 2A, 2B, 2C, 2D, 2E, 2F, 2G, 2H, 2I, and 2J are cross-sectional views of transistor structures evolving as the methods illustrated in FIG. 1 are practiced, in accordance with some embodiments;

FIG. 3 is a cross-sectional view of a monolithic IC structure comprising a transistor structure with a channel material in a stack with insulator material layers, in accordance with some embodiments;

FIG. 4 illustrates a mobile computing platform and a data server machine employing an IC device including transistor structures with a channel material in a stack with insulator material layers, in accordance with some embodiments; and

FIG. 5 is a functional block diagram of an electronic computing device, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

In accordance with embodiments herein, a transistor structure includes a 2D channel material. In some embodiments, the 2D material is a metal chalcogen channel material. Metal chalcogenide material, or another 2D material, may be advantageously implemented as channel material in a transistor structure where the channel material is vertically stacked. In such structures, 2D channel material on its own may be unable to survive subsequent transistor processing, such as formation of a high-k gate insulator and/or gate material adjacent to the 2D channel material.

In some embodiments, a 2D channel material is supported within a stack of materials that further includes one or more insulator (e.g., dielectric) materials above and/or below the 2D channel material. These supporting insulator layers may be non-sacrificial while other material layers within a starting material stack may be sacrificial (e.g., replaced with gate insulator and/or gate metal).

In some exemplary embodiments, a transistor structure includes one or more 2D material layers comprising a transition metal and a chalcogen. The 2D material layers extend between source and drain terminals of the transistor. One or more insulator layers may be above or below a channel region of each 2D material layer and a gate stack comprising a gate insulator may be in contact with the insulator layer(s). Accordingly, the insulator layers within the stack may both support a span of 2D material between source and drain terminals and also be incorporated into a gate insulator stack or other portion of a transistor structure.

As used herein, a channel region is a region of a material layer adjacent to a gate insulator and gate and that is to electrically coupled to the gate through the gate insulator. Accordingly, a channel region is a structural term specifying a physical location within a three-terminal transistor structure. As further used herein, a channel material is a material in the channel region. Accordingly, a channel material is a structural term specifying a material that is within a specific physical region of a three-terminal transistor structure.

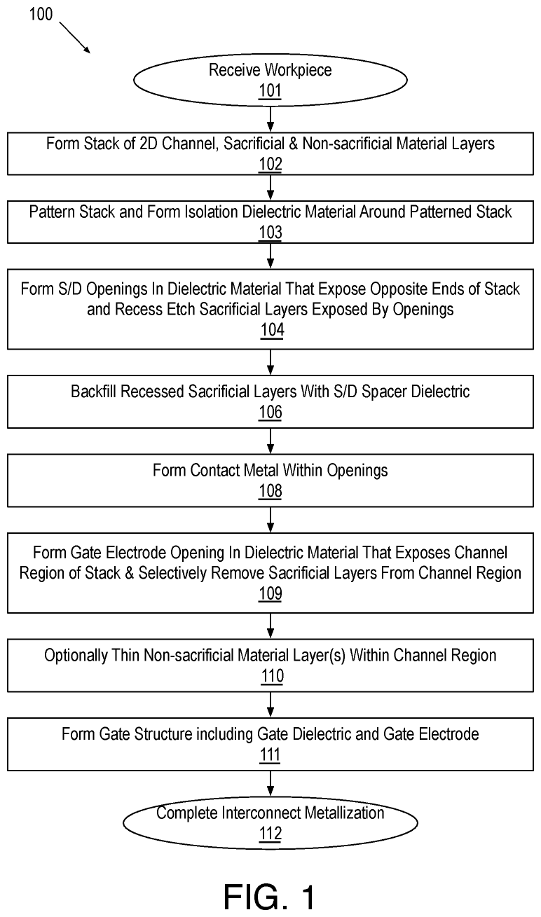

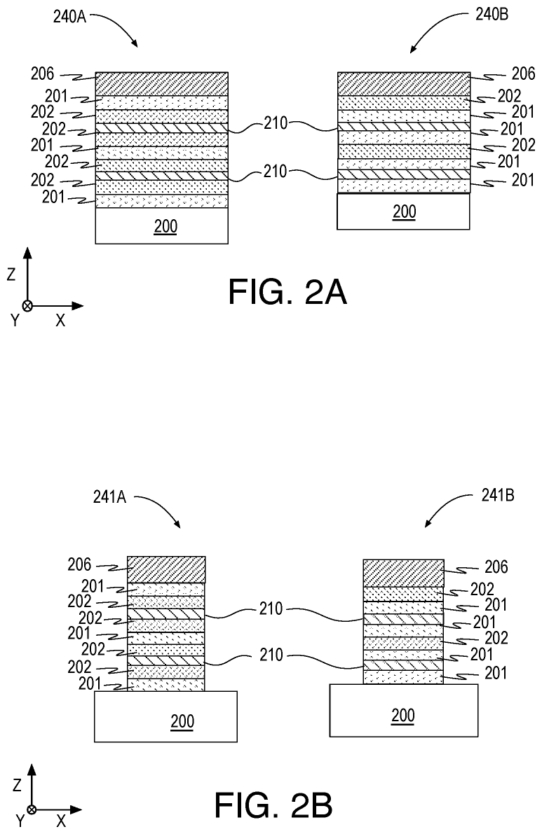

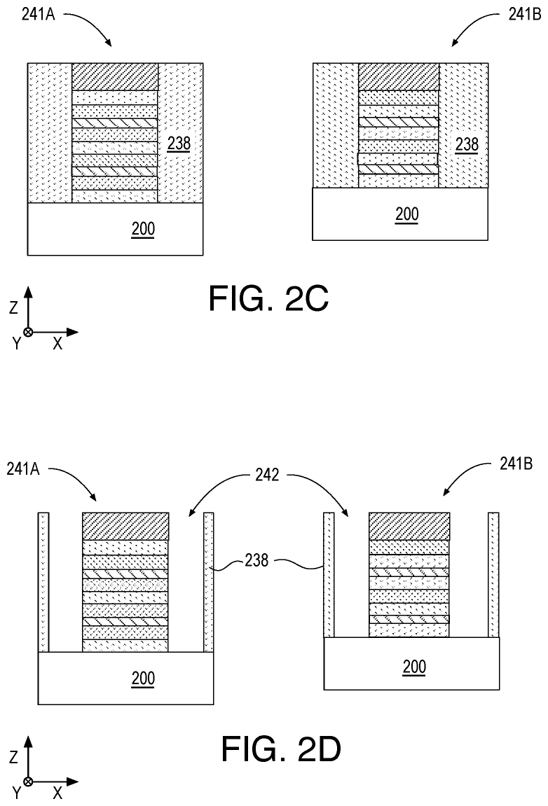

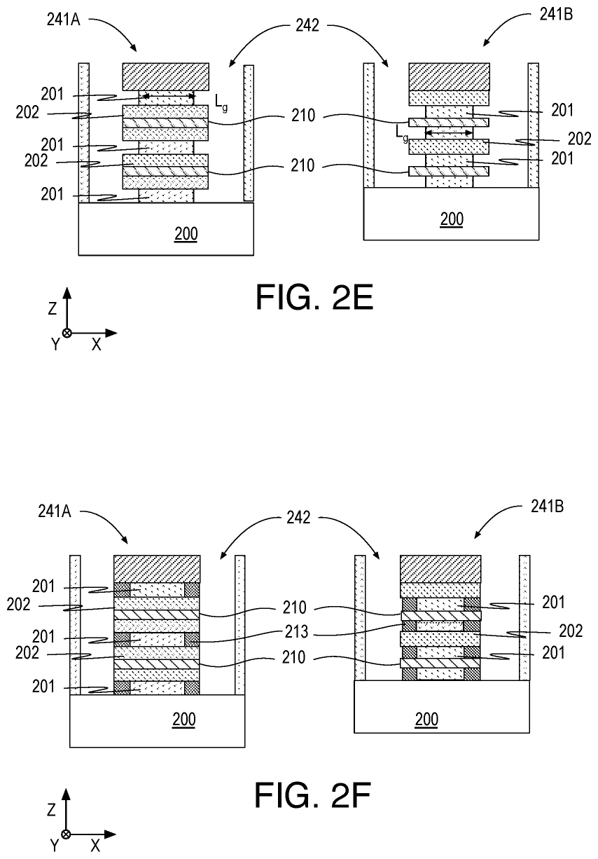

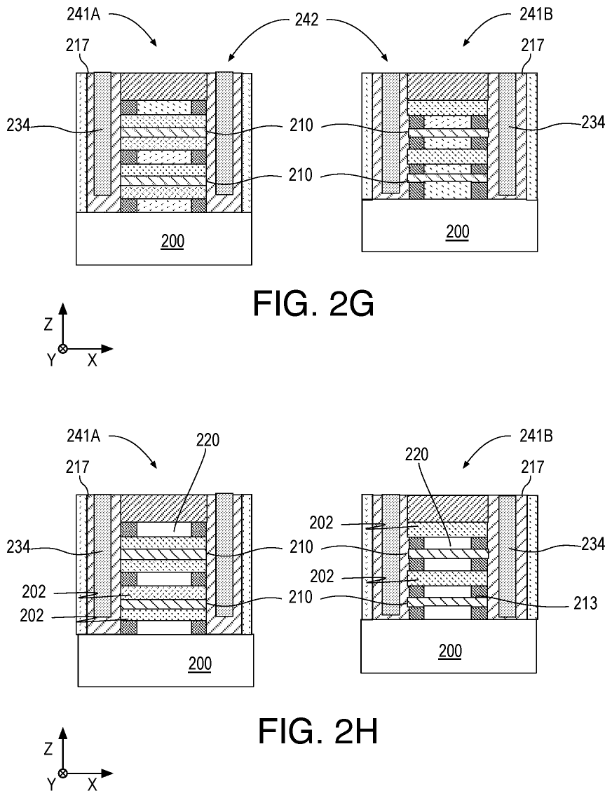

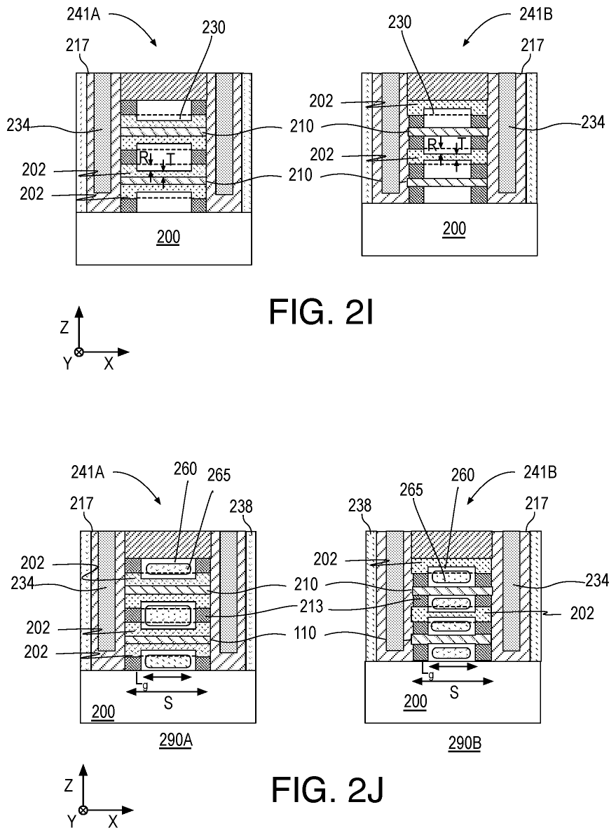

FIG. 1 is a flow diagram illustrating methods 100 for forming a transistor structure having insulator material layers above and/or below a channel material layer, in accordance with some embodiments. Methods 100 may be practiced as a wafer-level device fabrication process, for example. FIGS. 2A-2J are cross-sectional views of transistor structures evolving as the methods 100 are practiced in accordance with some exemplary embodiments. Methods other than methods 100 may be practiced to arrive at structures similar, if not identical to, those illustrated in FIG. 2A-2J. Likewise, methods 100 may be practiced to arrive at structures other than those illustrated in FIG. 2A-2J.

Methods 100 begin at input 101, where a workpiece is received for processing. In some examples, the substrate received at input 101 comprise a 300-450 mm diameter wafer. The substrate may include a substantially monocrystalline material and any number of thin film layers over the monocrystalline material.

At block 102, a multiple material layer stack including one or more channel material layers is formed over the substrate. Any number of channel material layers may be formed at block 102 within individual ones of the channel material layers physically separated from each other by at least one intervening sacrificial material layer and at least one intervening non-sacrificial material layer. Optionally, the multi-layer stack formed at block 102 may further include one or more hard mask layers and/or one or more etch stop layers.

Various material layers of the multilayer stack may be formed by practicing in succession any thin film deposition technique(s) suitable for each material layer composition, such as one or more of atomic layer deposition (ALD), chemical vapor deposition (CVD), plasma enhanced chemical vapor deposition (PECVD), metal-organic chemical vapor deposition (MOCVD), or molecular beam deposition/epitaxy (MBE). Notably, such thin film deposition processes need not be practiced directly upon the workpiece received at block 101 and may instead be fabricated on a donor substrate and then layer transferred from the donor to the workpiece received at input 101.

FIG. 2A illustrates a cross-sectional side views of two exemplary a multilayer stacks 240A and 240B over a substrate 200. In some exemplary embodiments, substrate 200 includes a crystalline material comprising one or more Group IV elements. For example, substrate 200 may comprise a single crystal of any of Si, Ge, SiGe, or GeSn. In other embodiments, the substrate material may comprise one or more (mono)crystalline Group III-V materials (e.g., GaAs), one or more (mono)crystalline Group III-N materials (e.g., GaN). Substrate 200 may further include one or more thin film material layers (not depicted). For example, substrate 200 may include underlying device layer(s) and/or metallization interconnect layers interconnect devices such as transistors, memories, capacitors, resistors, optoelectronic devices, switches, or any other active or passive electronic devices fabricated within the device layer(s).

Multilayer stacks 240A and 240B each include channel material layers 210. Although two channel material layers 210 are illustrated, a multilayer material stack may have only one channel material layer 210 or may have five or more (e.g., 5, 7, 9, etc.) channel material layers. Regardless of chemical composition, channel material layers 210 are referred to herein as “2D” layers as they have a thickness of less than two molecular monolayers. Channel material layers 210 may, for example have a thickness of not more than 1 nm.

In exemplary embodiments, individual ones of channel material layers 210 comprise a metal chalcogenide. In some embodiments, channel material layer 210 is a dichalcogenide (MC₂). However, because other oxidation states are possible channel material layers 210 may be better characterized as MCₓ with x being between 0.2 and 4. For embodiments herein, chalcogens include at least one of sulfur, selenium or tellurium (oxygen is excluded), with S or Se being particularly advantageous. Channel material layers 210 may therefore be MSₓ, MSeₓ, or MTeₓ, for example. In some metal chalcogenide embodiments, channel material layers 210 each have a thickness of about 0.33 nm.

In some exemplary embodiments, metal M is Cu, Zn, Zr, Re, Hf, Ir, Ru, Cd, Ni, Co, Pd, Pt, Ti, Cr, V, W Mo, Al, Sn, Ga, In, B, Ge, Si, P, As, or Sb. Channel material layers 210 may be predominantly one of these metals and one or more of the chalcogens. For example, the metal chalcogenide may be any of CuSₓ, CuSeₓ, CuTeₓ, ZnSₓ, ZnSeₓ, ZnTex ZrSₓ, ZrSeₓ, ZrTeₓ, ReSₓ, ReSeₓ, TeSeₓ RuSₓ, RuSeₓ, RuTeₓ IrSₓ, IrSeₓ, IrTeₓ, CdSₓ, CdSeₓ, CdTex NiSₓ, NiSeₓ, NiTeₓ CoSₓ, CoSeₓ, CoTeₓ PdSₓ, PdSeₓ, PtSeₓ PtSₓ, PtSeₓ, PtTeₓ TiSₓ, TiSeₓ, TiTeₓ CrSₓ, CrSeₓ, CrTex VSₓ, VSeₓ, VTeₓ, WSₓ, WSeₓ, WTeₓ MoSₓ, MoSeₓ, MoTeₓ, AlSₓ, AlSeₓ, AlTeₓ SnSₓ, SnSeₓ, SnTeₓ, GaSₓ, GaSeₓ, GaTex InSₓ, InSeₓ, InTex SbSₓ, SbSeₓ, SbTeₓ GeSₓ, GeSeₓ, GeTeₓ SiSₓ, SiSeₓ, or SiTeₓ. Of these compounds, MoSₓ, MoSeₓ, MoTeₓ and WSₓ, WSeₓ, WTeₓ may be particularly advantageous for implementing a transistor. In further embodiments, the metal includes multiple metals as M1M2 or M1M2M3 alloys along with one or more of S, Se, or Te. For example, channel material layers 210 may be InGaZnSeₓ.

Exemplary metal chalcogenides may be deposited by a molecular beam deposition process or a MOCVD process, for example. In some examples, the substrate is heated to over 400° C. (e.g., 450-1000° C.) in the presence of a chalcogen precursor gas, such as H₂S, H₂Se, or H₂Te. Since these exemplary precursors can also act as strong reducing agents, they may be combined or replaced with weaker reducing agents/stronger oxidizing agents. The deposition process may further include a vapor or liquid source of one or more metals, in addition to the chalcogen precursor. For example, a metal precursor may be the only source of metal incorporated into channel material layers 210. Although vapor/gas metalorganic sources are advantageous, liquid metalorganic precursors may also be used, for example with an MOCVD growth process that utilizes a bubbler.

In alternative embodiments, channel material layers 210 are a graphene-based (or graphene family) material such as graphene, hexagonal boron nitride (hBN, white graphene), boron and nitrogen co-doped graphene (BCN), fluorographene, or graphene oxide. In some other embodiments, channel material layers 210 are a 2D oxide such as a mica or a bismuth strontium calcium copper oxide (BSCCO) including MoO₃ or WO₃. In still other embodiments, channel material layers 210 are a 2D oxide such as a layered copper oxide including TiO₂, MnO₂, V₂O₅, TaO₃, RuO₂, or the like. In other embodiments, channel material layers 210 are a 2D oxide such as a perovskite-type including LaNb₂O₇, (Ca,Sr)₂Nb₃O₁₀, Bi₄Ti₃O₁₂, Ca₂Ta₂TiO₁₀, or the like. In still other embodiments, channel layers 210 are a hydroxide including Ni(OH)₂ or Eu(OH)₂ or the like.

Multilayer stacks 240A and 240B each further include sacrificial material layers 201 and non-sacrificial material layers 202. Sacrificial material layers 201 may have any chemical composition that allows for such material layers to be etched or otherwise removed selectively relative to channel material layers 210 and relative to non-sacrificial material layers 202. In some examples, sacrificial layers 201 all have substantially the same composition. Sacrificial material layers 201 may comprise, for example, a metal or silicon and at least one of oxygen or nitrogen. In some embodiments, sacrificial material layers 201 are one of silicon oxide, silicon nitride, aluminum oxide, aluminum nitride, molybdenum oxide, molybdenum nitride, or hafnium oxide.

One or more non-sacrificial material layers 202 may be incorporated into multilayer stacks with channel material layers 210 and may, for example, structurally support channel material layers 210. Non-sacrificial material layers 201 have a chemical composition distinct from each of channel material layers 210 and sacrificial material layers 202. Non-sacrificial material layers 202 are advantageously electrical insulators, such as a dielectric or ferroelectric. Non-sacrificial material layers 202 may be tuned to have a suitable (compressive or tensile) stress of a suitable magnitude for improving overall structural robustness.

In some embodiments, non-sacrificial material layers 202 comprise a metal or silicon and at least one of oxygen or nitrogen. Non-sacrificial material layers 202 may comprise a metal, such as Al, Hf, or Zr, and oxygen (e.g., Al₂O₃, HFO₂, ZrO₂, etc.), for example. Such dielectric materials are known to have a relative permittivity of at least 10 in their bulk form. However, for lower parasitic capacitance and/or lower short channel effects, non-sacrificial material layers 202 advantageously comprise a dielectric material associated with a relative permittivity less than 10, and more advantageously comprise a dielectric material associated with a relative permittivity less than 3.5.

In some embodiments, non-sacrificial material layers 202 comprise silicon and at least one of oxygen or nitrogen. In some examples, non-sacrificial material layers 202 comprise primarily silicon and nitrogen (e.g., Si₃N₄). In some other examples, non-sacrificial material layers 202 comprise silicon, nitrogen, and oxygen (e.g., SiON). In some specific examples, non-sacrificial material layers 202 are substantially silica (e.g., SiO₂). In other embodiments, non-sacrificial material layers 202 comprise a doped silica further including carbon (e.g., SiOC) for any even lower relative permittivity (e.g., <3.2).

Multilayer stack 240A illustrates one advantageous embodiment including a non-sacrificial material layer 202 both above and below each channel material layer 210. In this example, non-sacrificial material layers 202 are in direct contact with each channel material layer 210 and channel material layer 210 is in direct contact with only non-sacrificial material layers 202. Multilayer stack 240B illustrates an alternative embodiment where the relative positions of sacrificial material layers 201 and non-sacrificial material layers 202 are swapped relative to multilayer stack 240A. Hence in multilayer stack 240B sacrificial material layers 201 are directly contacting each channel material layer 210 and channel material layers 210 are in direct contact with only sacrificial material layers 201. For such embodiments, there may be fewer non-sacrificial material layers 202 for a given number of channel material layers 210. For example, in multilayer stack 240B there is only one non-sacrificial material layers 202 between two channel material layers 210 while there are two non-sacrificial material layers 202 between two channel material layers 210 in multilayer stack 240A.

Multilayer stacks 240A, 240B further include a hardmask material layer 206, which may have any chemical composition but is advantageously of a composition resistant to etch processes and potentially distinct from all other material layers. As one example, hardmask material layer 206 may be primary silicon and carbon (e.g., silicon carbide). Sacrificial material layers 201, non-sacrificial material layers 202, and hardmask layer 206 may each be formed with ALD, CVD, or PECVD processes, for example.

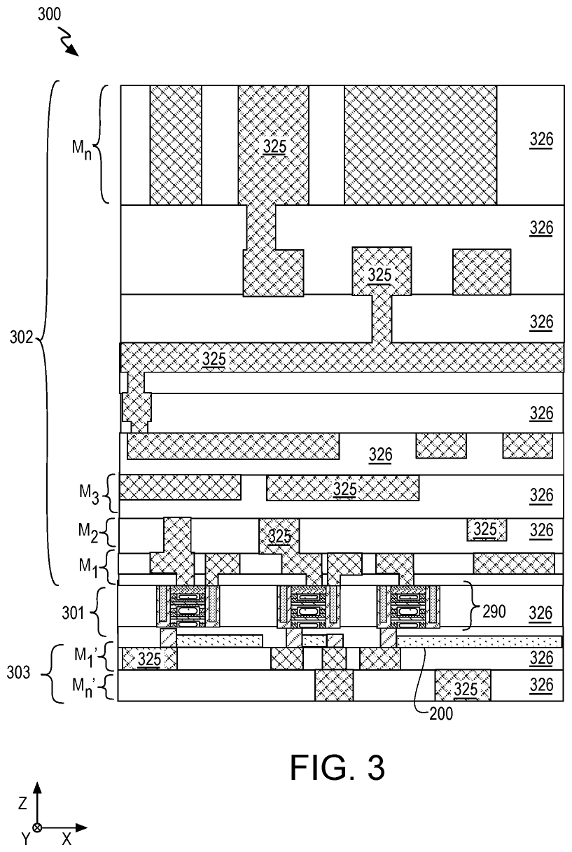

Returning to FIG. 3, methods 100 continue at block 103, where the multilayer stack formed at operation 102 is patterned, for example into a fin structure. An isolation dielectric material is then formed around the patterned feature comprising the multilayer stack. The multilayer stack may be patterned using any suitable technique or techniques such as lithography and etch techniques. Isolation dielectric material may also be formed using any technique or techniques known to be suitable.

FIG. 2B illustrates a cross-sectional side view of fin structures 241A and 241B that result from pattern etching multilayer stacks 240A and 240B, respectively. In some embodiments, a pattern imaged in a photoresist layer (not depicted) is transferred into hardmask material layer 206. A remainder of multilayer stack 240A, 240B is then etched on the basis of the patterned hardmask material layer 206. As shown, fin patterning may define metal chalcogen layers 210, along with sacrificial material layers 201 and non-sacrificial material layers 202. Although dimensions may vary with implementation, in some exemplary embodiments fin length (x-dimension) ranges from 10-100 nm while fin width (y-dimension) may range from 4-10 nm. FIG. 2C further illustrates a cross-sectional side view of fin structures 241A and 241B after the formation and planarization of an isolation dielectric material 238, which may have any chemical composition suitable as a dielectric, such as, but not limited to silicon nitride and/or silicon dioxide.

Returning to FIG. 1, methods 100 continue at block 104 where source and drain terminal openings are formed in the isolation dielectric material. These openings exposed opposite ends of the features patterned at block 103. Once exposed, in some exemplary embodiments the sacrificial material layers are recessed, for example with a selective etch process. In the examples illustrated in FIG. 2D, isolation dielectric material 238 has been etched to form openings 242 that reveal source and drain ends of fin structures 241A, 241B.

FIG. 2E further illustrates a cross-sectional side view of a fin structures 241A and 241B after an etch process laterally (e.g., x-dimension) recesses an exposed end of sacrificial material layers 201 relative to ends of non-sacrificial material layers 202 and channel material layers 210. In fin structure 241A, the recess etch reveals end portions of non-sacrificial material layers 201. In fin structure 241B, the recess etch reveals end portions of metal chalcogen layers 210. Sacrificial material layers 201 may etched selectively with wet etch chemistry or plasma-based atomic layer etch (ALE) techniques. The magnitude of the recess etch may vary with implementation as a gate length L_{g} associated with the length of a channel region of a transistor structure is dependent upon the extent of recess etch. In some examples, the recess is in the range of 1-20 nm and advantageously less than 3 nm.

Returning to FIG. 1, methods 100 continue at block 106, where a spacer dielectric material is deposited to at least partially backfill the recessed portion of the sacrificial material layers. The spacer dielectric material may be anisotropically etched and then optionally recessed or thinned (e.g., isotropically). The spacer dielectric material may be formed using any suitable deposition and etch techniques. FIG. 2F illustrates formation of a spacer dielectric material 213. In some embodiments, a bulk dielectric material is deposited within openings 242 and planarization techniques are practiced to provide a substantially planar top surface. Although spacer dielectric material 213 may have any chemical composition, in exemplary embodiments spacer dielectric material 213 is a material associated with a relative permittivity of less than 10 and advantageously no more than 3.5.

In some advantageous embodiments, spacer dielectric material 213 is a low k dielectric material (k<3.2), such as, a carbon doped silicon oxide. In some embodiments, spacer dielectric material 213 has substantially the same composition as non-sacrificial material layers 202. Although not illustrated, for fin structure 241B spacer dielectric material 213 may be thinned to expose some end length of channel material layers 210. Similarly for fin structure 241A, non-sacrificial material layers 202 may be laterally recessed to expose some end length of channel material layers 210 in preparation for the formation of source and drain terminals.

Returning to FIG. 1, methods 100 continue block 108, where source and drain terminals are formed within the openings that expose opposite ends of the fin structures. In exemplary embodiments, a contact metal liner is first deposited and then a fill metal is deposited over the contact metal liner. In some embodiments, the source and drain terminal metal(s) are deposited by ALD or PVD. The source and drain contact metal may include any metal(s) of sufficiently low contact resistance. Source and drain fill metal may be formed by practicing any suitable technique such as electroplating, PVD, etc. Following metal deposition, source and drain terminal metallization may be planarized with surrounding material(s).

FIG. 2G illustrates a cross-sectional view of fin structures 241A and 241B following deposition of source and drain terminals comprising a contact metal liner 217 and a fill metal 234. As shown, source and drain contact metal liner 217 may be substantially conformal to exposed ends of channel material layers 210. In exemplary embodiments, contact metal liner 217 is in direct contact with an end portion of channel material layers 210. Contact metal liner 217 may have any composition suitable for the composition of channel material layers 210. In some embodiments where channel material layers 210 comprise a metal chalcogenide (e.g., WSₓ or WSex, MoSₓ or MoSeₓ), contact metal liner 217 may be antimony, ruthenium, titanium, for example. Fill metal 234 may include any suitable fill metal such as, but not limited to, titanium, cobalt, tungsten, copper, or ruthenium.

Returning to FIG. 1, methods 100 continue at block 109, where at least another portion of the sacrificial material layer(s) are removed. In some embodiments, a patterned photoresist layer is formed and etch techniques are used to selectively expose the sacrificial layers. The exposed sacrificial layers may then be removed using any etch techniques selective to the chemical composition of the sacrificial material layers. In the example shown in FIG. 2H remaining portions of sacrificial material layers 201 have been removed, forming openings 220. In some embodiments, access to sacrificial layers 201 is provided by patterned openings in the isolation dielectric material that are into or out of the page (i.e., y-dimension). Sacrificial material layers may be removed with any selective etch techniques (e.g., wet chemical or ALE). For fin structure 241A, channel material layers 210 remain protected and/or supported by non-sacrificial material layers 202 along the entire span between source and drain terminals. However, in fin structure 241B channel material layers 210 are exposed and free standing, but supported by spacer dielectric material 213 and an underlying/overlying non-sacrificial material layer 202 that also spans the length between the source and drain terminals.

Returning to FIG. 1, methods 100 continue at block 110 where the non-sacrificial material layers may be optionally thinned with a wet etch and/or ALE process. As only a portion of the non-sacrificial material layers within the channel regions are exposed, an optional thinning process may be performed at block 110. Such thinning may be to increase the dimensions of the opening that is to be back filled with a gate structure. Depending on the embodiment, thinning the non-sacrificial material at block 110 may also ensure any thickness of non-sacrificial material left within the channel region of the structure will be suitable as a portion of gate insulator material. Depending on the composition of the non-sacrificial material, thinning performed at block 110 may tune transistor threshold voltages, for example.

FIG. 2I illustrates some examples of thinning non-sacrificial material layers 202. In FIG. 2I, dashed lines illustrate an as-deposited surface of non-sacrificial material layers 202 with recess regions 230 recessed from the dashed line by a recess amount R so that non-sacrificial material layers 202 have a channel region thickness T. Channel region thickness T is less than the as-deposited thickness of non-sacrificial material layers 202 and may vary, for example, from 1-3 nm. Although the amount of recess may vary, in some examples recess amount R ranges from 1-3 nm.

Returning to FIG. 1, methods 100 continue at block 111, where gate structures are formed within the openings vacated by the removal of sacrificial material layers at block 109.

In some embodiments, the gate structure includes a gate insulator and a gate material. The gate insulator may be formed by conformal deposition using ALD, for example. Similarly, the gate material may be formed using metal deposition techniques including ALD, plating techniques, or the like. In some embodiments, both the gate insulator and the gate material are formed through the access openings formed at block 109.

FIG. 2J illustrates a cross-sectional side view of transistor structures 290A and 290B after a gate structure is formed over fin structures 241A, 241B, respectively. Depending on implementation, each of transistor structures 290A, 290B is an n-type metal oxide semiconductor (NMOS) device or a p-type metal oxide semiconductor (PMOS) device. In some exemplary embodiments, channel material layers 210 are an n-type metal chalcogenide, such as MoS₂ or WS₂. In other embodiments, channel material layers 210 are a p-type metal chalcogenide, such as MoSe₂ or WSe₂.

In the exemplary embodiment, a gate structure includes a gate insulator 260 and gate material 265 such that gate (electrode) material 265 is separated from channel material layers 210 by at least gate insulator material 260. In transistor structure 290A, gate insulator material 260 is separated from channel material layers 210 by a channel region thickness of non-sacrificial material layer 202. Non-sacrificial material layer 202 remaining with the channel region therefore is a portion of the gate stack (i.e., another layer of gate insulator). In transistor structure 290B non-sacrificial material layer 202 is not retained as a portion of the gate stack and gate insulator material 260 is in direct contact with channel material layers 210.

Gate insulator material 260 may have a relatively high dielectric constant(F) and advantageously has a relative permittivity exceeding that of non-sacrificial material layer 202. In some high-K gate dielectric embodiments, gate insulator material 260 is a metal oxide comprising oxygen and one or more metals, such as, but not limited to, aluminum, hafnium, zirconium, tantalum, or titanium. In other embodiments, gate insulator material 260 is a ferroelectric. In still other embodiments, gate insulator material 260 may be primarily silicon oxide (e.g., lacking carbon present in non-sacrificial material layer 202).

Gate material 265 may be or include a metal such as but not limited to platinum, nickel, molybdenum, tungsten, palladium, gold, alloys thereof, or nitrides such as titanium nitride, tantalum nitride, tungsten silicon nitride, etc. In some embodiments, gate material 265 includes a work function metal and a fill metal (not depicted).

With three terminals fabricated, transistor structures 290A and 290B are substantially complete nanoribbon transistor structures comprising a stack of 2D channel material layers that span a lateral distance S from a source terminal to a drain terminal. In addition to the 2D channel material layers, transistor structures 290A and 290B further comprise non-sacrificial material layers 202 that also span the lateral distance S from a source terminal to a drain terminal. In contrast, the gate structure comprising gate insulator 260 and gate material 265 span a lateral distance less than S (e.g., only the channel length L_{g}).

While the lateral lengths of non-sacrificial material layers 202 and channel material layers 210 may be substantially the same (as illustrated), in alternative embodiments their lengths may differ. However, non-sacrificial material layers 202 generally have a length sufficient to ensure some portion of the non-sacrificial material layers are retained through completion of transistor structure fabrication.

Returning to FIG. 1, methods 100 continue at output 112 where any fabrication process known in the art may be practiced, for example to interconnect the transistor structure(s) fabricated in blocks 102-111 into integrated circuitry with a monolithic IC die. Further processing at output 112 may include forming interconnect features including metallization routings and vias, dicing, packaging, assembly, and so on. The resultant apparatus (e.g., integrated circuit die) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

2D channel transistor structures comprising a support material layer in accordance with embodiments herein may be integrated into a wide variety of ICs and computing systems that include such ICs. FIG. 3 is a cross-sectional view of an IC structure 300, in accordance with some embodiments further illustrating transistor structures 290, which may be either 290A or 290B as described above, for example. IC structure 300 illustrates a portion of a monolithic IC die that includes FEOL interconnect metallization levels 302 over and/or on a front side of a device layer 301 that includes stacked ribbon or wire (RoW) transistor structures 290 (i.e., 290A or 290B) including 2D channel material and a support material, for example as described elsewhere herein.

Within IC structure 300, front-side interconnect metallization levels 302 include interconnect metallization 325 electrically insulated by dielectric material 326. In the exemplary embodiment illustrated, front-side interconnect metallization levels 302 include metal-one (M₁), metal-two (M₂), metal-three (M₃) and metal-n (Mₙ) interconnect metallization levels. Interconnect metallization 325 may be any metal(s) suitable for IC interconnection. Interconnect metallization 325, may be, for example, an alloy of predominantly Cu, an alloy of predominantly W, an alloy of predominantly Ru, an alloy of predominantly Al, an alloy of predominantly Mo, etc. Dielectric material 326 may be any dielectric material known to be suitable for electrical isolation of monolithic ICs. In some embodiments, dielectric material 326 comprises silicon, and at least one of oxygen and nitrogen. Dielectric material 326 may be SiO, SiN, or SiON, for example. Dielectric material 326 may also be a low-K dielectric material (e.g., having a dielectric constant below that of SiO₂). Although metal-one is illustrated to have lines and vias of different heights, for example in accordance with some embodiments described above, any of the other metallization levels may have lines and vias of different heights.

IC structure 300 further includes back-side interconnect metallization levels 303. Within interconnect metallization levels 303, interconnect metallization 325 is again electrically insulated by dielectric material 326. Back-side metallization levels 303 may comprise any number of metallization levels over, or on, a back side of transistor structures 290. In the illustrated example back-side metallization, metallization levels 303 include a metallization level M₁′ through nearest to transistor structures 290 (e.g., opposite M₁) through an uppermost back-side metallization level Mₙ′.

As shown, regions of substrate material 200 may remain between device layer 301 and back side metallization levels 303. Although not illustrated, regions of substrate material 200 may include a device layer further comprising, for example, silicon CMOS transistors. Accordingly, device layer 301 may be a backend device layer over any known frontend CMOS device layer. Furthermore, although IC structure 300 includes one device level 301 comprising transistor structures 290, there may be multiple device levels 301 located within the various interconnect metallization levels. Each of multiple device levels 301 may similarly include a plurality of transistor structures 290.

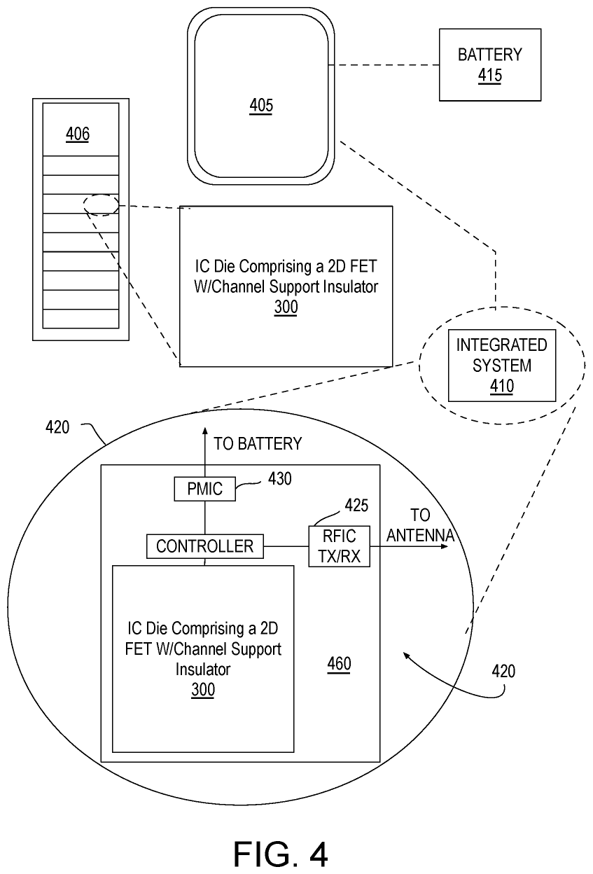

FIG. 4 illustrates a mobile computing platform 405 and a data server machine 406 employing a packaged IC die including 2D channel material layers and support material layers, for example as described elsewhere herein. Server machine 406 may be any commercial server, for example including any number of high-performance computing platforms disposed within a rack and networked together for electronic data processing, which in the exemplary embodiment includes a packaged IC die comprising IC structure 300, for example as described elsewhere herein.

The mobile computing platform 405 may be any portable device configured for each of electronic data display, electronic data processing, wireless electronic data transmission, or the like. For example, the mobile computing platform 405 may be any of a tablet, a smart phone, laptop computer, etc., and may include a display screen (e.g., a capacitive, inductive, resistive, or optical touchscreen), an integrated system 410, and a battery 415.

As illustrated in the expanded view 420, IC structure 300 is further coupled to host component 460. One or more of a power management integrated circuit (PMIC) 430 or RF (wireless) integrated circuit (RFIC) 425 including a wideband RF (wireless) transmitter and/or receiver may be further coupled to host component 460. PMIC 430 may perform battery power regulation, DC-to-DC conversion, etc., and so has an input coupled to battery 415 and with an output providing a current supply to other functional modules. As further illustrated, in the exemplary embodiment, RFIC 425 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G and beyond.

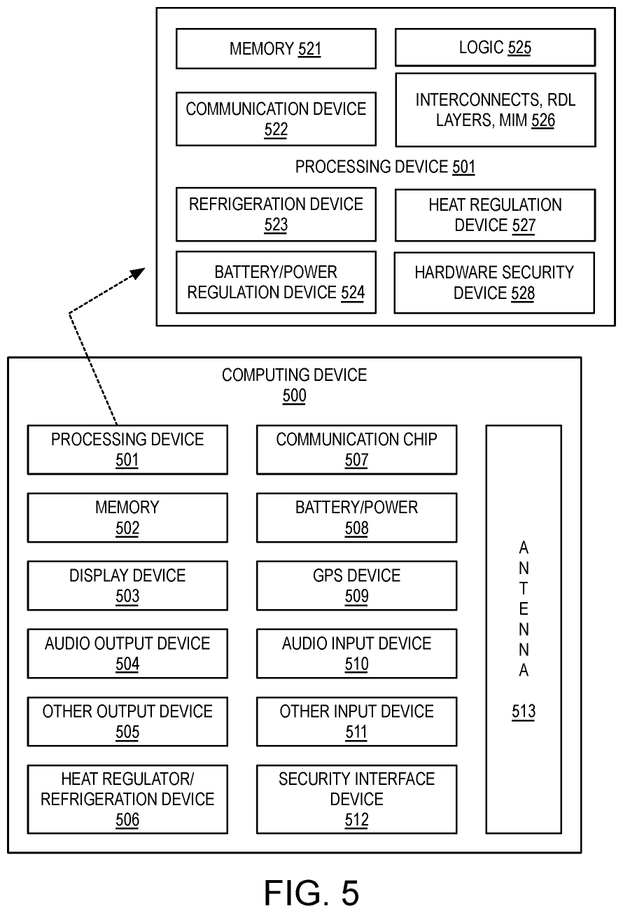

FIG. 5 is a block diagram of a cryogenically cooled computing device 500 in accordance with some embodiments. For example, one or more components of computing device 500 may include any of the devices or interconnect structures discussed elsewhere herein. A number of components are illustrated in FIG. 5 as included in computing device 500, but any one or more of these components may be omitted or duplicated, as suitable for the application. In some embodiments, some or all of the components included in computing device 500 may be attached to one or more printed circuit boards (e.g., a motherboard). In some embodiments, various ones of these components may be fabricated onto a single system-on-a-chip (SoC) die. Additionally, in various embodiments, computing device 500 may not include one or more of the components illustrated in FIG. 5, but computing device 500 may include interface circuitry for coupling to the one or more components. For example, computing device 500 may not include a display device 503, but may include display device interface circuitry (e.g., a connector and driver circuitry) to which display device 503 may be coupled.

Computing device 500 may include a processing device 501 (e.g., one or more processing devices). As used herein, the term processing device or processor indicates a device that processes electronic data from registers and/or memory to transform that electronic data into other electronic data that may be stored in registers and/or memory. Processing device 501 may include a memory 521, a communication device 522, a refrigeration/active cooling device 523, a battery/power regulation device 524, logic 525, interconnects 526 (i.e., optionally including redistribution layers (RDL) or metal-insulator-metal (MIM) devices), a heat regulation device 527, and a hardware security device 528.

Processing device 501 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 501 may include a memory 502, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 521 includes memory that shares a die with processing device 501. This memory may be used as cache memory and may include embedded dynamic random-access memory (eDRAM) or spin transfer torque magnetic random-access memory (STT-M RAM).

Computing device 500 may include a heat regulation/refrigeration device 506. Heat regulation/refrigeration device 506 may maintain processing device 501 (and/or other components of computing device 500) at a predetermined low temperature during operation. This predetermined low temperature may be any temperature discussed elsewhere herein.

In some embodiments, computing device 500 may include a communication chip 507 (e.g., one or more communication chips). For example, the communication chip 507 may be configured for managing wireless communications for the transfer of data to and from computing device 500. The term “wireless” and its derivatives may be used to describe circuits, devices, systems, methods, techniques, communications channels, etc., that may communicate data through the use of modulated electromagnetic radiation through a nonsolid medium.

Communication chip 507 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 507 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 507 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 507 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 507 may operate in accordance with other wireless protocols in other embodiments. Computing device 500 may include an antenna 513 to facilitate wireless communications and/or to receive other wireless communications (such as AM or FM radio transmissions).

In some embodiments, communication chip 507 may manage wired communications, such as electrical, optical, or any other suitable communication protocols (e.g., the Ethernet). As noted above, communication chip 507 may include multiple communication chips. For instance, a first communication chip 507 may be dedicated to shorter-range wireless communications such as Wi-Fi or Bluetooth, and a second communication chip 507 may be dedicated to longer-range wireless communications such as GPS, EDGE, GPRS, CDMA, WiMAX, LTE, EV-DO, or others. In some embodiments, a first communication chip 507 may be dedicated to wireless communications, and a second communication chip 507 may be dedicated to wired communications.

Computing device 500 may include battery/power circuitry 508. Battery/power circuitry 508 may include one or more energy storage devices (e.g., batteries or capacitors) and/or circuitry for coupling components of computing device 500 to an energy source separate from computing device 500 (e.g., AC line power).

Computing device 500 may include a display device 503 (or corresponding interface circuitry, as discussed above). Display device 503 may include any visual indicators, such as a heads-up display, a computer monitor, a projector, a touchscreen display, a liquid crystal display (LCD), a light-emitting diode display, or a flat panel display, for example.

Computing device 500 may include an audio output device 504 (or corresponding interface circuitry, as discussed above). Audio output device 504 may include any device that generates an audible indicator, such as speakers, headsets, or earbuds, for example.

Computing device 500 may include an audio input device 510 (or corresponding interface circuitry, as discussed above). Audio input device 510 may include any device that generates a signal representative of a sound, such as microphones, microphone arrays, or digital instruments (e.g., instruments having a musical instrument digital interface (MIDI) output).

Computing device 500 may include a global positioning system (GPS) device 509 (or corresponding interface circuitry, as discussed above). GPS device 509 may be in communication with a satellite-based system and may receive a location of computing device 500, as known in the art.

Computing device 500 may include another output device 505 (or corresponding interface circuitry, as discussed above). Examples include an audio codec, a video codec, a printer, a wired or wireless transmitter for providing information to other devices, or an additional storage device.

Computing device 500 may include another input device 511 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 500 may include a security interface device 512. Security interface device 512 may include any device that provides security measures for computing device 500 such as intrusion detection, biometric validation, security encode or decode, managing access lists, malware detection, or spyware detection. In some examples, security interface device 512 comprises OTP ROM further including a via MIM fuse, for example as described elsewhere herein.

Computing device 500, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the disclosure is not limited to the embodiments so described, but instead can be practiced with modification and alteration without departing from the scope of the appended claims. For example, the above embodiments may include specific combinations of features as further provided below.

In first examples, a transistor structure comprises a first channel material layer in a stack with a second channel material layer. Each of the first and second channel material layers span a distance between a source terminal and a drain terminal. A dielectric material layer is between the first and second channel material layers. The dielectric material layer also spans the distance between the source and drain terminals. A gate structure is between the first and second channel material layers and spans less than the distance between the source terminal and the drain terminal. The gate structure comprises a gate insulator in contact with the dielectric material layer and a gate material in contact with the gate insulator.

In second examples, for any of the first examples the channel material layer comprises a metal and a chalcogen, the dielectric material layer has first composition associated with a first relative permittivity, and the gate insulator has a second composition associated with a second relative permittivity, greater than the first permittivity.

In third examples, for any of the second examples the dielectric material layer comprises oxygen and silicon.

In fourth examples, for any of the third examples the dielectric material layer comprises carbon.

In fifth examples, for any of the second through fourth examples the gate insulator comprises a metal and oxygen, the metal substantially absent from the dielectric material layer.

In sixth examples, for any of the first through fifth examples the dielectric material layer is in direct contact with the first channel material layer or the second channel material layer.

In seventh examples for any of the sixth examples the dielectric material layer is in direct contact with the first channel material layer and the transistor structure further comprises a second dielectric material layer in direct contact with the second channel material layer.

In eighth examples, for any of the seventh examples the dielectric material layer and the second dielectric material layer are both between the first and second channel material layers, and the transistor structure further comprises a third dielectric material layer and a fourth dielectric material layer. The first channel material is between the dielectric material layer and the third dielectric material layer, and the second channel material is between the second dielectric material layers and the fourth dielectric material layer.

In ninth examples, for any of the eighth examples the second, third and fourth dielectric material layers have substantially the same composition as the dielectric material layer.

In tenth examples, for any of the first through ninth examples a transistor structure further comprises a spacer dielectric material between the gate structure and each of the source and drain terminals. The dielectric material layer has a first thickness between the spacer dielectric material and the first channel material layer, and a second thickness, less than the first thickness, between the gate structure and the first channel material.

In eleventh examples, for any of the first through tenth examples the gate structure is between the dielectric material layer and the first channel material layer.

In twelfth examples, for any of the first through eleventh examples the metal comprises molybdenum or tungsten, the chalcogen comprises sulfur or selenium, and the first and second channel material layers comprise a transition metal dichalcogenide monolayer.

In thirteenth examples, a system comprises an integrated circuit (IC) die and a power supply coupled to the IC die. The IC die comprises a transistor structure. The transistor structure comprises a stack of nanoribbons coupled between a source terminal and a drain terminal, a gate structure coupled to channel regions of the nanoribbons, the gate structure comprising a gate insulator and a gate material. The transistor comprises an intervening dielectric material layer between each of the nanoribbons and in contact with the source terminal and drain terminal. The intervening dielectric material layer has a different composition than the gate insulator. The transistor structure comprises a spacer between the gate insulator and the source terminal or drain terminal.

In fourteenth examples, for any of the thirteenth examples each of the nanoribbons comprises a metal and a chalcogen the intervening dielectric material layer is a first dielectric material layer in direct contact with a first of the nanoribbons, and the system further comprises a second dielectric material layer in direct contact with a second of the nanoribbons.

In fifteenth examples, for any of the fourteenth examples the first and second dielectric material layers have substantially the same composition.

In sixteenth examples, a method comprises receiving a multilayer stack comprising a plurality of channel material layers interleaved with a plurality of sacrificial layers and a plurality of intervening dielectric material layers. The method comprises removing the sacrificial layers and forming a gate structure in contact with the intervening dielectric material layers. The gate structure comprises a gate insulator in contact with the intervening dielectric material layers and a gate material in contact with the gate insulator. The method comprises coupling a source terminal and a drain terminal to the channel material layers.

In seventeenth examples, for any of the sixteenth examples removing the sacrificial layers comprises removing a first sacrificial layer from between first and second ones of the intervening dielectric material layers, and forming the gate structure comprises backfilling a space between the first and second ones of the intervening dielectric material layers with the gate structure.

In eighteenth examples, for any of the sixteenth through seventeenth examples the method further comprises etching through a partial thickness of the first and second ones of the intervening dielectric material layers after removing the sacrificial material.

In nineteenth examples for any of the eighteenth examples the etching comprises an atomic layer etch process.

In twentieth examples, for any of the sixteenth through nineteenth examples the channel material layers each comprise a metal and a chalcogen and the intervening dielectric material layers comprise oxygen and silicon.

However, the above embodiments are not limited in this regard, and, in various implementations, the above embodiments may include the implementation of only a subset of such features, the implementation a different order of such features, the implementation of a different combination of such features, and/or the implementation of additional features than those features explicitly listed. The scope of the disclosure should, therefore, be determined with reference to the appended claims, along with the full scope of equivalents to which such claims are entitled.

In sixteenth examples, a method comprises receiving a multilayer stack comprising a plurality of channel material layers interleaved with a plurality of sacrificial layers and a plurality of intervening dielectric material layers. The method comprises removing the sacrificial layers and forming a gate structure in contact with the intervening dielectric material layers. The gate structure comprises a gate insulator in contact with the intervening dielectric material layers and a gate material in contact with the gate insulator. The method comprises coupling a source terminal and a drain terminal to the channel material layers.

In seventeenth examples, for any of the sixteenth examples removing the sacrificial layers comprises removing a first sacrificial layer from between first and second ones of the intervening dielectric material layers, and forming the gate structure comprises backfilling a space between the first and second ones of the intervening dielectric material layers with the gate structure.

In eighteenth examples, for any of the sixteenth through seventeenth examples the method further comprises etching through a partial thickness of the first and second ones of the intervening dielectric material layers after removing the sacrificial material.

In nineteenth examples for any of the eighteenth examples the etching comprises an atomic layer etch process.

In twentieth examples, for any of the sixteenth through nineteenth examples the channel material layers each comprise a metal and a chalcogen and the intervening dielectric material layers comprise oxygen and silicon.

However, the above embodiments are not limited in this regard, and, in various implementations, the above embodiments may include the implementation of only a subset of such features, the implementation a different order of such features, the implementation of a different combination of such features, and/or the implementation of additional features than those features explicitly listed. The scope of the disclosure should, therefore, be determined with reference to the appended claims, along with the full scope of equivalents to which such claims are entitled.

What is claimed is:

1. A transistor structure, comprising:
a first channel material layer in a stack with a second channel material layer, wherein each of the first and second channel material layers span a distance between a source terminal and a drain terminal;
a dielectric material layer between the first and second channel material layers, wherein the dielectric material layer also spans the distance between the source and drain terminals; and
a gate structure between the first and second channel material layers, wherein the gate structure spans less than the distance between the source terminal and the drain terminal, and wherein the gate structure comprises:
a gate insulator in contact with the dielectric material layer; and
a gate material in contact with the gate insulator.

2. The transistor structure of claim 1, wherein:
the channel material layer comprises a metal and a chalcogen;
the dielectric material layer has first composition associated with a first relative permittivity; and
the gate insulator has a second composition associated with a second relative permittivity, greater than the first permittivity.

3. The transistor structure of claim 2, wherein the dielectric material layer comprises oxygen and silicon.

4. The transistor structure of claim 3, wherein the dielectric material layer comprises carbon.

5. The transistor structure of claim 2, wherein the gate insulator comprises a metal and oxygen, the metal substantially absent from the dielectric material layer.

6. The transistor structure of claim 1, wherein the dielectric material layer is in direct contact with the first channel material layer or the second channel material layer.

7. The transistor structure of claim 6, wherein the dielectric material layer is in direct contact with the first channel material layer and the transistor structure further comprises a second dielectric material layer in direct contact with the second channel material layer.

8. The transistor structure of claim 7, wherein:
the dielectric material layer and the second dielectric material layer are both between the first and second channel material layers; and
the transistor structure further comprises a third dielectric material layer and a fourth dielectric material layer, wherein:
the first channel material is between the dielectric material layer and the third dielectric material layer; and
the second channel material is between the second dielectric material layer and the fourth dielectric material layer.

9. The transistor structure of claim 8, wherein the second, third and fourth dielectric material layers have substantially the same composition as the dielectric material layer.

10. The transistor structure of claim 1, further comprising a spacer dielectric material between the gate structure and each of the source and drain terminals; and wherein:
the dielectric material layer has a first thickness between the spacer dielectric material and the first channel material layer; and
the dielectric material layer has a second thickness, less than the first thickness, between the gate structure and the first channel material.

11. The transistor structure of claim 1, wherein the gate structure is between the dielectric material layer and the first channel material layer.

12. The transistor structure of claim 1, wherein:
the metal comprises molybdenum or tungsten;
the chalcogen comprises sulfur or selenium; and
the first and second channel material layers comprise a transition metal dichalcogenide monolayer.

13. A system, comprising:
an integrated circuit (IC) die comprising a transistor structure, the transistor structure comprising:
a stack of nanoribbons coupled between a source terminal and a drain terminal;
a gate structure coupled to channel regions of the nanoribbons, the gate structure comprising a gate insulator and a gate material; and
an intervening dielectric material layer between each of the nanoribbons and in contact with the source terminal and drain terminal, the intervening dielectric material layer having a different composition than the gate insulator; and
a spacer between the source or drain structure and the gate structure; and
a power supply coupled to the IC die.

14. The system of claim 13, wherein:
each of the nanoribbons comprises a metal and a chalcogen;
the intervening dielectric material layer is a first dielectric material layer in direct contact with a first of the nanoribbons; and
the system further comprises a second dielectric material layer in direct contact with a second of the nanoribbons.

15. The system of claim 14, wherein the first and second dielectric material layers have substantially the same composition.

16. A method, comprising:
receiving a multilayer stack comprising a plurality of channel material layers interleaved with a plurality of sacrificial layers and a plurality of intervening dielectric material layers;
removing the sacrificial layers;
forming a gate structure in contact with the intervening dielectric material layers, the gate structure comprising a gate insulator in contact with the intervening dielectric material layers and a gate material in contact with the gate insulator; and
coupling a source terminal and a drain terminal to the channel material layers.

17. The method of claim 16, wherein:
removing the sacrificial layers comprises removing a first sacrificial layer from between first and second ones of the intervening dielectric material layers; and
forming the gate structure comprises backfilling a space between the first and second ones of the intervening dielectric material layers with the gate structure.

18. The method of claim 16 further comprising etching through a partial thickness of the first and second ones of the intervening dielectric material layers after removing the sacrificial material.

19. The method of claim 18, wherein the etching comprises an atomic layer etch process.

20. The method of claim 16, wherein:
the channel material layers each comprise a metal and a chalcogen; and
the intervening dielectric material layers comprise oxygen and silicon.
